(19) United States
(12) Patent Application Publication
(10) Pub. No.: US 2011/0297837 A1
(43) Pub. Date: Dec. 8, 2011

(54) RADIATION DETECTION MODULE AND RADIATION IMAGE-CAPTURING DEVICE

(75) Inventors: Takafumi Ishitsu, Hitachi (JP); Isao Takahashi, Hitachi (JP); Katsutoshi Tsuchiya, Hitachi (JP); Kazuma Yokoi, Hitachi (JP); Yuichiro Ueno, Hitachi (JP)

(73) Assignee: HITACHI, LTD., Tokyo (JP)

(21) Appl. No.: 13/201,914

(22) PCT Filed: Feb. 17, 2010
(86) PCT No.: PCT/JP2010/052363

§ 371 Date: Aug. 17, 2011

(30) Foreign Application Priority Data
Feb. 17, 2009 (JP) 2009-034147

(51) Int. Cl. G01T 1/24; H01L 27/146

(52) U.S. Cl. 250/370.08; 250/370.01

(57) ABSTRACT

The radiation detection module (20) is provided with a semiconductor element (1) having a plurality of pixels (Pn), radiation detection elements (30) in which a plurality of first electrodes (31n) are arranged along one side of the semiconductor element (1), and a second electrode (32m) is disposed astride a plurality of pixels (Pn) along the other side, and which output detection signals when a radioactive ray comes incident on the detection pixels (Pn), and a support PCB (21) placed to stand along the direction in which the radioactive ray comes incident. The support PCB (21) has a connection section (21a) detachably connectable to an external connecting section. Radiation detection elements (30) are connected on the support PCB (21) to fabricate a signal read-out circuit having mutually-perpendicular wiring in a pseudo way and that the incident position of the radioactive ray is identified by coincidence determination of the detection signals.

### BACKGROUND OF THE INVENTION

1. Field of the Invention

The present invention relates to a radiation detection module and a radiation imaging device. More particularly, the present invention relates to a technique for achieving a high quality image and facilitating an assemble process of the device.

2. Relevant Technical Field to the Invention

A conventional radiation detection module has one read-out circuit for one pixel to read out an individual detection signal induced by radioactive ray, and identifies an incident position of radiation. However, the packaging density of read-out circuit limits the size of radiation detection area and pixel density. Therefore, increases in an area of radiation incident plane and density of a read-out circuit are limited.

Therefore, DSSD (Double-Sided Silicon Strip Detector) has been invented as a system which reads out numerous pixels with a small number of read-out circuits. The DSSD has a plurality of strip electrodes on each of upper surface and lower surface of a detector perpendicular to each other, and identifies the incident position of radiation by reading out signal from both surfaces. In this way, the principle to read out (N×M) pixels by (N+M) read-out circuits has been established (for example, refer to Non-Patent Document 1).

However, the technology of Non-Patent Document 1 requires a unit block of pixels to be approximate in a square shape, in order to obtain the effect of the reduction of the read-out circuits. Therefore, when one unit block of pixels becomes out of order, the function of radiation detection capability is lost in the square region. To interpolate the lost pixel data are hard and cause image defect.

Furthermore, with respect to the technology of Non-Patent Document 1, an incident radioactive ray comes from perpendicular direction against the surface of the detector electrode, it is necessary to increase the thickness of the detector in order to prevent the penetration of the incident radioactive ray and increase the detection efficiency. However, if the thickness of the detector increases, the charge collection efficiency decrease because of the decrease of the mobility of electric charge induced in the detector. Consequently, in the technology of Non-Patent Document 1, it becomes unable to measure a generating charge amount accurately.

For example, Patent Document 1 discloses a technology in which the direction of incident radioactive ray is parallel to the surface of the electrode of the detection element, to keep the thickness of the detector and the detection efficiency. Further, the technology of Patent Document 1 discloses that signal from the electrode of detector connected on a PCB (Printed Circuit Board) arranged separately, resulting in the reduction of read-out circuit by using the same principal of the DSSD.

### Documents of Conventional Technology

### Patent Document

Patent Document 1: JP-A 2006-119095

### Non-Patent Document

Non-Patent Document 1: The Third Edition of Radiation Measuring Handbook (Nikkan Kogyo Shimbun Ltd.) Page 559

### SUMMARY OF THE INVENTION

### Problem to be Solved by the Invention

However, in the technology of Patent Document 1, the signal wires are directly contacted to the detector and inserted into the connector. To avoid the damage of detector in in inserting the connecter is difficult because the signal wire has no enough strength from external force. Therefore, when the detection element is inserted into or pulled off the connector, it is necessary to be careful not to cause a damage to the signal wires. Furthermore, if the pixel density of the detector panel increases, both the density and the number of signal wire will increase. And therefore, it is necessary to take a special care of electrical insulation on the design aspect and the purpose of the density growth of the pixel is not usually achieved sufficiently.

The present invention has been made to solve the foregoing problems, and it is therefore an object of the present invention to provide a radiation detection module and a radiation image-capturing device enabling improvement of the quality of the image and facilitating mounting and assembling radiation detection elements.

### Means for Solving Problem

To attain the above-mentioned object, the present invention is characterized in that a radiation detection module is provided with a radiation detection element including a semiconductor element having a plurality of pixels, a plurality of first electrodes arrayed on a surface of the semiconductor element, a second electrode disposed on the other surface of the semiconductor element over the plurality of pixels, wherein the radiation detection element outputs the detection signals to the first electrode and the second electrode when a radioactive ray comes incident on the pixels, a support PCB being placed in parallel with a direction in which the radioactive ray comes incident, and supporting a plurality of the radiation detection elements arranged perpendicularly to the incident direction; and a connector being detachably connected to an external connecting unit, bias voltage being applied thereto from the connecting unit, outputting the detection signals to the connecting unit, and mechanically holding the support PCB to the connecting unit, wherein the plurality of the first electrodes are connected each other on the support PCB, a position on which the radioactive ray comes incident is identified by coincidence detection of the first and second electrodes.

In the present invention thus constructed, the number of signal wire decreases, resulting in facilitating the constitution of the external connecting unit and the connection section holding the support PCB at the connecting unit, and arranging the adjacent radiation detection module at short intervals. By arranging m radiation detection elements each having n pixels, even if (m×n) pixels are arranged in one radiation detection module, the number of readout wiring of the detection signals is able to reduce to (m+n). Furthermore, previously resistances and capacitors have been mounted on the outside of the connection unit. However, by moving them on the support PCB, the density of wiring to the external side can be decrease. At the same time, the high voltage DC component decreases or is shut off, resulting in reducing the portion where high voltage is applied, among the area of a signal contact point of wiring disposed in the connection section and the connecting unit. In addition, by forming an aggregation of a unit of the pixels in a rectangle shape, data can be interpolated from surrounding pixel data when one pixel goes down.

### Effect of the Invention

According to the present invention, a radiation detection module and a radiation image-capturing device enabling improvement of the quality of the image and facilitation of mounting and maintenance thereof of detecting elements are obtained.

### BRIEF DESCRIPTION OF THE DRAWINGS

FIG. 1 is an overall view of a radiation image-capturing device in an embodiment according to the present invention;

FIG. 2 is an inner structural drawing of a radiation image-capturing device in an embodiment according to the present invention;

FIG. 3A is a perspective view of a radiation detection module in an embodiment according to the present invention, FIG. 3B shows a radiation detection element;

FIG. 4A is a top view, and FIG. 4B is a side view both of a radiation detection module in an embodiment according to the present invention, FIG. 4C is a top view, FIG. 4D is a side view both of a radiation detection module in a deformation example; and

FIG. 5 is a circuit diagram of a radiation detection module in an embodiment according to the present invention.

### MODE FOR CARRYING OUT THE INVENTION

Hereinafter, embodiments of a radiation image-capturing device and a radiation detection module according to the present invention will be described in detail with reference to the accompanying drawings. In the following description, as an example, a semiconductor gamma camera device which detects gamma rays, a kind of radiation, will be described.

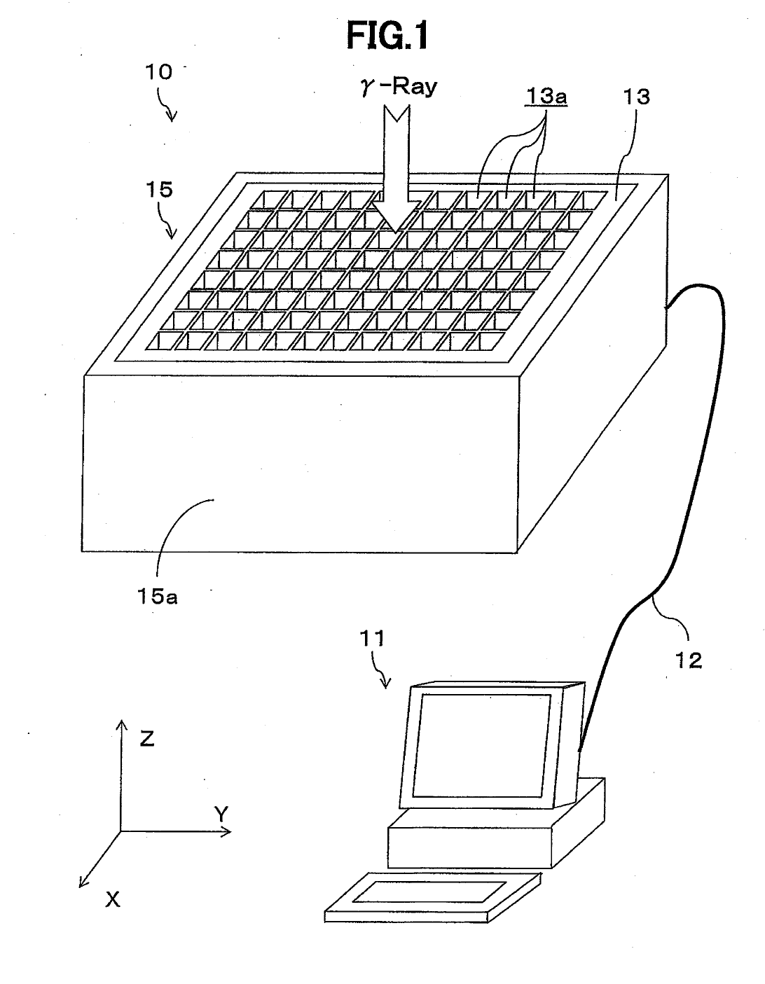

As shown in an overall view of FIG. 1, a radiation image-capturing device 10 comprises an imaging unit 15 including a collimator 13 arranged to be an incidence plane of the radioactive ray and fixed to a flame 15a, and the image display unit 11 displaying an image by collecting data from the imaging unit 15 through a cable 12. Further, as explained below with reference to drawings, the flame 15a accommodates a main part of the radiation image-capturing device 10 in an internal space thereof.

Generally, a Radio Isotope which emits gamma rays having energy equal to about tens of keV (kilo electron volt) to hundreds of keV, is used as an object to be imaged on a gamma camera (the radiation image-capturing device 10). A measurement is performed for every one event of incident radioactive ray upon the imaging unit 15, and an image obtained by integrating the event is displayed on the image display unit 11.

The collimator 13 is constructed by using a material having a high shielding property such as lead, and has a lot of holes 13a so that incident radioactive ray only from a particular direction (Z-axis direction as indicated in FIG. 1) pass therethrough. When the radioactive ray, being emitted from a radiation source located outside the imaging unit 15, passes through the collimator 13, a planar image of brightness distribution of the radioactive ray is produced by the imaging unit 15.

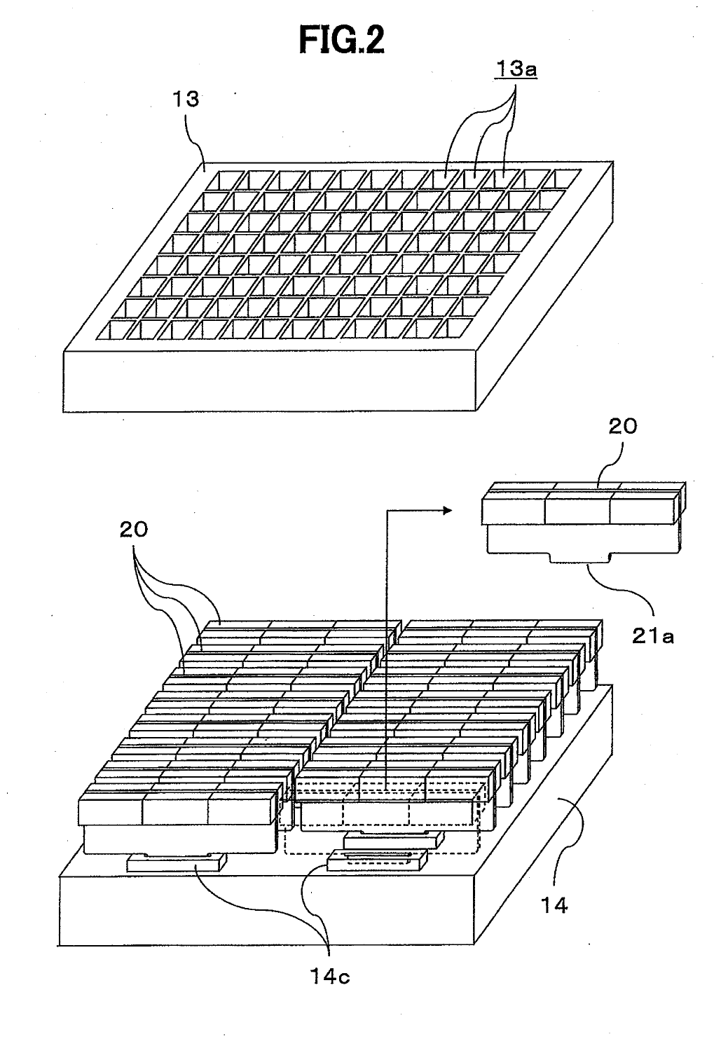

The brightness distribution of the radioactive ray being produced as the planar image, is treated by a radiation detection module 20 (refer to FIG. 2) and a signal detection block 14 both located inside of the imaging unit 15. Then, it is sent to the image display unit 11 after information on such as detection points of the radioactive ray and detection energy of the radioactive ray is converted into digital data. This image display unit 11 generates an image on the basis of the digital data of the detection point and the energy, additionally using correction data collected previously, and displays the image on a screen.

Furthermore, SPECT (Single Photon Emission Computed Tomography), a kind of a nuclear medicine diagnosis apparatus, can obtain three-dimensional information of a tomographic image of a subject who is administered a radiopharmaceutical, by rotating this imaging unit 15 around the subject, or by setting up a plurality of the imaging units 15 around the subject.

FIG. 2, a partial exploded perspective view, shows the structure packed in the flame 15a (refer to FIG. 1).

This inner structure comprises a plurality of the radiation detection modules 20 each of which detects incident radioactive ray. A plurality of the radiation detection modules 20 are arranged in a plane configuration so as to be parallel with inner walls of the collimator 13. These radiation detection modules 20 have a connection section 21a that is capable of being fit in and detachable from a connecting unit 14c located on a surface of the signal detection block 14.

As mentioned above, the connection section 21a does not only get the radiation detection module 20 held mechanically by the external connecting unit 14c, but also get the detection module 20 applied with bias voltage being applied from a side of the signal detection block 14, via the connecting unit 14c, and get the detection signals guided to the signal detection block 14 via the connecting unit 14c.

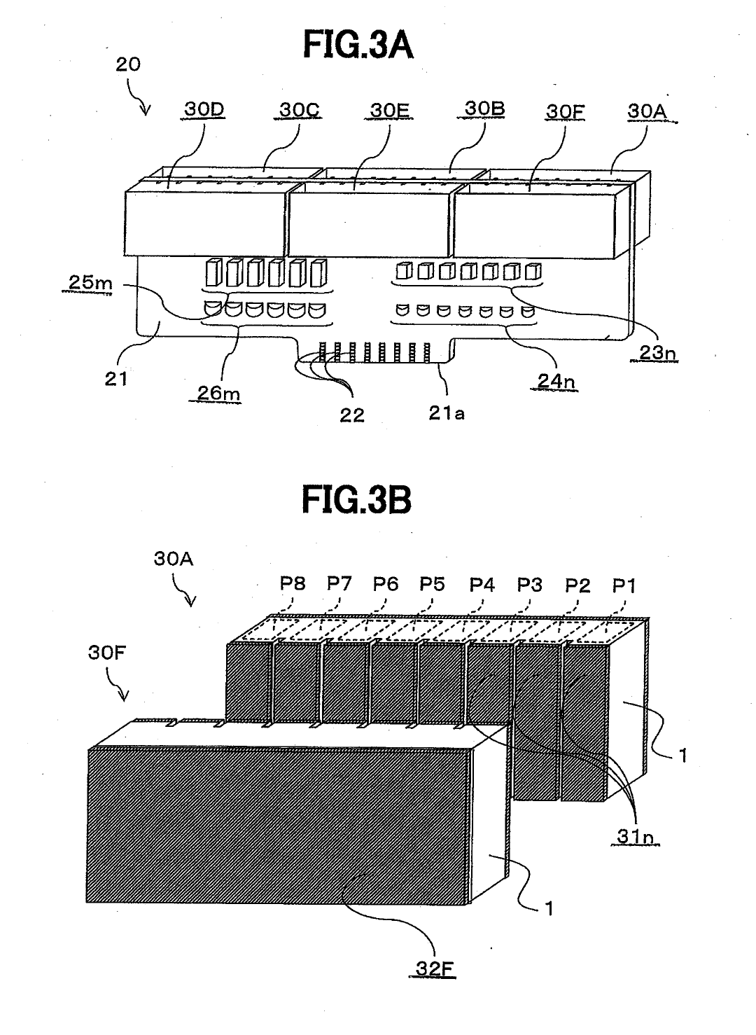

The connection section 21 a gets electrical connection at the surface of contact point 22 (refer to FIG. 3A) by mechanically contacting a contact point (not shown) of the connecting unit 14c.

Furthermore, the structure of the connection section 21a is not limited to the one which is formed on an extended surface of a support PCB 21 as shown in drawings. Pin insertion type connector or bellows type connector can be adopted depending on cases.

The signal detection block 14 amplifies and detects a small analog electric signal which comes from the radiation detection modules 20 detecting radiation. Further, the signal detection block 14 involves a high voltage generating circuit which supplies high voltage bias to the radiation detection modules 20.

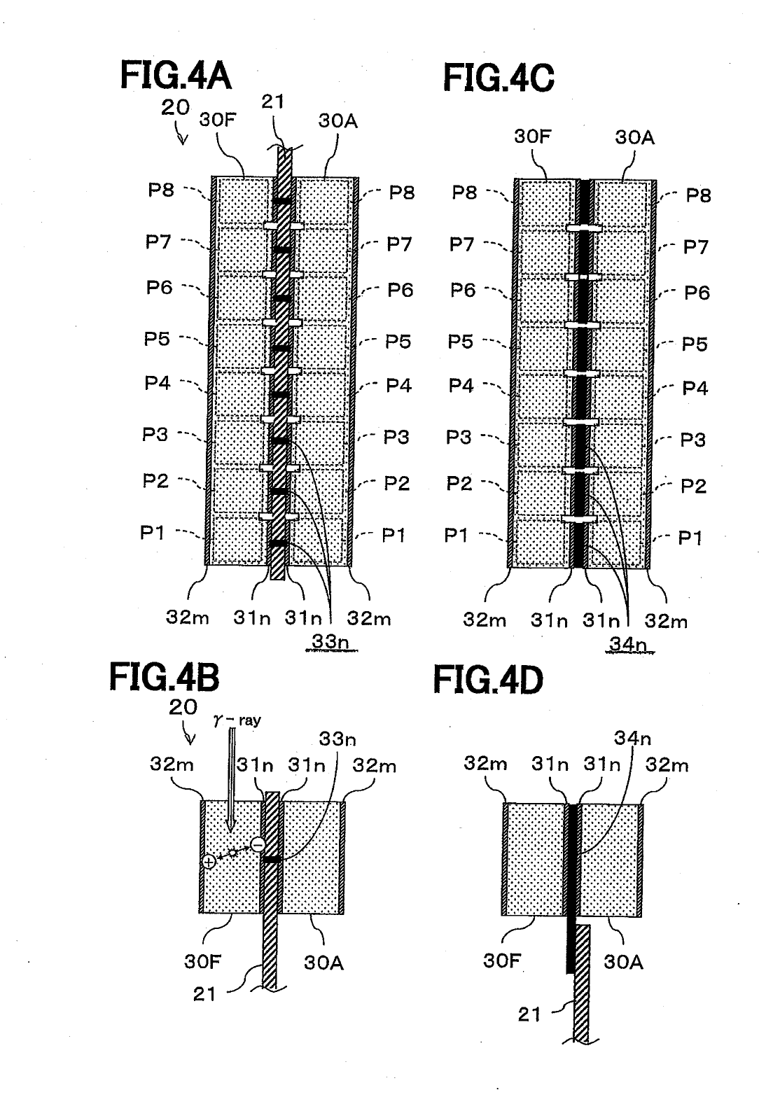

On the other hand, the circuit which amplifies and detects the detection signals is contains in an ASIC (Application Specific Integrated Circuit) which is designed and manufactured on custom-made based on a specification of a system. This ASIC measures a pulse hight of the amplified detection signals. Next, the time stamp information when the detection signal is detected, and address information of a detection pixel Pn (refer to FIG. 4A) which outputs the detection signal, are added to this pulse height information so as to form a digital signal. Finally, this digital signal is transmitted to the image display unit 11 via the cable 12 (refer to FIG. 1).

Additionally, the address information of a detection pixel Pn is, as described hereinafter, represented with binary codes.

As shown in the perspective view of FIG. 3A, the detection modules 20 comprises the support PCB 21, a plurality of radiation detection elements 30 (30A to 30F), a plurality of low voltage bias resistances 23n (n=1 to 8), a plurality of low voltage coupling capacitors 24n (n=1 to 8), a plurality of high voltage bias resistances 25m (m=A to F) and a plurality of high voltage coupling capacitors 26m (m=A to F) are mounted onto the support PCB 21.

A plurality of the radiation detection elements 30 are arranged on each of surface of the support PCBs 21 each of which is mounted in parallel with the direction of incident radioactive ray (Z-axis of FIG. 1), to be arrayed perpendicular to the direction of incident (30A to 30C on one surface, 30D to 30F on other surface, each surface 3, total of 6 in FIG. 3A).

As shown in FIG. 3B, a semiconductor element 1 constitutes one radiation detection element 30, comprises a plurality of the detection pixels Pn (8 pieces for P1 to P8 in FIG. 3B).

On one side of the semiconductor element 1, a plurality of first electrodes 31n (n=1 to 8), being divided for each detection pixel Pn (n=1 to 8), are arranged on one side of the radiation detection element 30 facing to the support PCB 21. Further, on the other side of the semiconductor element 1, one second electrode 32m is arranged being a common electrode over a plurality of detection pixels Pn of the radiation detection element 30 (refer accordingly to FIG. 4A, 4B).

This radiation detection element 30 is constituted by the semiconductor element 1 made of such materials as CdTe and CZT. The first electrode 31n and the second electrode 32m are arranged on both surfaces of the semiconductor element 1, and Pt or In is deposited on a crystal surface by sputtering, In addition, the formation of divided first electrode 31 n is performed by using a mask in depositing or cutting out an electrode surface by singulation after depositing to the whole surface of the electrode.

Although the above example of the radiation detection element 30 is provided with the semiconductor element 1 into which a plurality of the detection pixels Pn are integrated, the structure is not limited thereto. The radiation detection element 30 may be provided so as to be separated for each pixel.

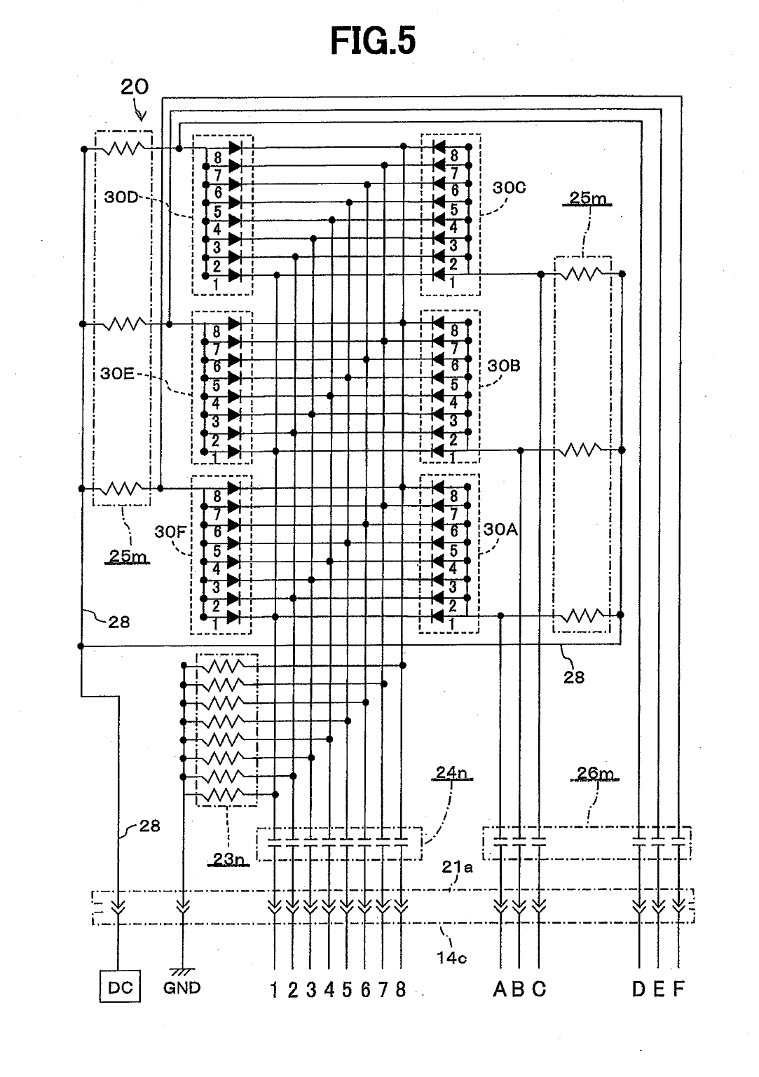

As shown partially in FIG. 4A, 4B, the radiation detection module 20 has the first electrodes 31n (n=1 to 8) which face each other across the support PCB 21 and are electrically connected to each other through a conductor 33n through the support PCB 21. Here, among the first electrodes 31n (n=1 to 8) mounted onto the support PCB 21, ones having an identical n-number are connected to a common wire (refer accordingly to FIG. 5). Therefore, for example, the first electrodes 31n which face each other across the support PCB 21, are connected electrically to each other by perforating this support PCB 21 to form a through hole, and filling up the through hole with the conductor 33n.

Furthermore, as a modified example, shown in FIG. 4C, 4D, two first electrode 31n, 31n may be arranged so as to face each other across a conducting plate 34n which is isolated electrically and is placed from outer edge of the support PCB 21.

Hereinafter, a preferable embodiment will be described using FIG. 3A. As many the high voltage bias resistances 25m (m=A to F) as the high voltage coupling capacitors 26m (m=A to F) are mounted on the support PCB 21, and the number of them corresponds to the number of radiation detection elements 30 (30A to 30F) mounted onto the support PCB 21. Further, the number of the low voltage bias resistances 23n (n=1 to 8) and the number of the low voltage coupling capacitors 24n (n=1 to 8) both mounted onto the support PCB 21, corresponds to the number of detection pixels Pn (n=1 to 8) which one second electrode 32m has.

In addition, the above-described resistance 23n, 25m and the capacitor 24n, 26m, as signal processing element mounted onto the support PCB 21, are shown for illustrative purposes, so any elements mounted into the signal detection block 14 (refer to FIG. 2) can be transferred onto the support PCB 21. Specifically, it is considerable that above-described ASIC or like which transforms a small analog signal (the detection signal) to a digital signal, is mounted onto the support PCB 21.

Each of the high voltage bias resistances 25m is correspondingly mounted to be connected with one of the second electrodes 32m (m=A to F), and connected between DC power (refer to FIG. 5) providing bias voltage. Note that the high voltage bias resistance 25m is an element to prevent a signal provided from an electrode from flowing into a bias power source (refer accordingly to FIG. 5).

Each of the high voltage coupling capacitors 26m is correspondingly mounted to be connected with one of second electrodes 32m (m=A to F), and connected between an ASIC circuit of the signal detection block 14 (refer to FIG. 2). In this way, a high voltage direct-current component (DC component) of the detection signal output from the second electrode 32m is removed. Then, as will be described below, only a signal of electric charge generating within the radiation detection element 30 is delivered into the ASIC circuit.

One terminal of each of the low voltage bias resistances 23n is connected to all (6 pieces) of the first electrodes 31n which have the same n-number out of the radiation detection elements 30 (30A to 30F) on the support PCB 21. The other terminal of each of the low voltage bias resistances 23n is connected to the ground electric potential (refer accordingly to FIG. 5). Therefore, the low voltage bias resistance 23n prevents a signal from flowing out to the ground. One terminal of each of the low voltage coupling capacitor 24n is also connected to all (6 pieces) of the first electrodes 31 n which have the same n-number out of the radiation detection elements 30 (30A to 30F) on the support PCB 21. The other terminal of each of the low voltage coupling capacitor 24n is connected to the ASIC circuit of the signal detection block 14 (refer to FIG. 2). In this way, a low voltage direct-current component (DC component) out of the detection signal output from the first electrode 31n is removed. Then, as will be described below, only the signal component of electric charge generating within the radiation detection element 30 is guided into the ASIC circuit.

The low voltage bias resistance 23n and the low voltage coupling capacitor 24n may be formed within the ASIC as a particular kind of circuit, without being mounted onto the support PCB 21.

Next, the principle of the detection of the radioactive ray on the radiation detection module 20 will be described with reference to a side view in FIG. 4B.

When a radioactive ray comes incident on any of detection pixels Pn of the radiation detection element 30, pairs of electrons and holes are generated, with an electric charge generated in the semiconductor element 1. Further, as there is a high electric field between the first electrode 31n and the second electrode 32m in the semiconductor element 1, generated electrons and generated holes move in the opposite direction, being drawn to either of the first electrode 31n and the second electrode 32m.

In this way, when the radioactive ray comes incident on, it is transformed to an electric signal, and the detection signal output from the first electrode 31n and the second electrode 32m are guided to the ASIC circuit via the connection section 21a, after being removed bias voltage respectively by the low voltage coupling capacitor 24n and the high voltage coupling capacitor 26m. Further, the coincidence detection being determined in the ASIC circuit, thereby from the information of two wiring which is determined that the detection signals are sent out simultaneously, the address information to identify incident position of the radioactive ray is obtained.

In the above description, as an example, is shown the structure in which a pair of radiation detection elements 30 are arranged on the both sides of the support PCB 21. However, the radiation detection elements 30 may be arranged on only one side of the support PCB 21. Furthermore, in the description, as an example of the structure of the radiation detection module 20, is shown the structure in which eight detection pixels Pn (n=8) are arranged on one radiation detection element 30, further six radiation detection elements 30 (m=6) are mounted on one support PCB 21. In this way, in the case that the number of pixels are (m×n), the number of readout wiring of detecting signal may be (m+n) (Besides that, ground wiring and bias voltage wiring are needed).

Here, the number of m or n is not limited to any particular ones. For the purpose of explanation, the case of (m≠n) is shown to avoid confusing comprehension. However, the case of (m=n) results in a better reduction effect of the number of wiring against the number of pixels.

Furthermore, the embodiment is shown as an example for the case that a negative bias voltage is applied to the second electrode 32m (refer to FIG. 4B), however, a positive bias voltage may be applied thereto.

The circuit of the radiation detection module 20 will be described with reference to FIG. 5.

The wiring from the second electrodes 32m (refer to FIG. 4B) which are on all of the radiation detection elements 30 (30A to 30F), are connected to a high voltage bias wiring 28 via corresponding high voltage bias resistances 25m (25A to 25F).

Further, as high a voltage as appropriately −500V is applied to this high voltage bias wiring 28.

In addition, a direction of voltage and a voltage value, of the high bias voltage is appropriately set according to the direction or thickness of both of the diode characteristic of the radiation detection element 30.

Furthermore, the high voltage coupling capacitor 26m is connected to each wiring from the second electrode 32m, thereby a bias voltage (DC voltage component) applied to this second electrode 32m is removed, and only the detection signal output from the radiation detection element 30 is allowed to pass. After the bias voltage is removed, this detection signal is drawn out of the radiation detection module 20 via the connection section 21a. In this way, by removing the high DC voltage component in the radiation detection module 20, in the area of the contact point 22 of the connection section 21a, portions on which the high voltage is applied are reduced, and the reliability improves.

Furthermore, there are totally 6 wires (A to F) by which the detection signal is took out from the second electrode 32m on which the high voltage is applied. Here, as high voltage is applied only to the high voltage bias wiring 28 (refer to FIG. 5), the constitution to ensure electric insulation of the connection section 21a and the connecting unit 14c is comparatively simple.

All of 6 first electrodes 31n, whose n-numbers (n=1 to 8) are identical to each other, and each of which arrayed on the surface of one of the radiation detection elements 30 (30A to 30F) contacting to the support PCB 21 (refer to FIG. 4), are connected respectively to one wiring (hereinafter described “wiring from the first electrode 31 n”), and connected to the ground wiring GND via the low voltage bias resistance 23n. Further, the low voltage coupling capacitors 24n are connected to the wiring from the first electrode 31n. By this low voltage coupling capacitors 24n, the DC voltage component out of the detection signal output from the first electrode 31n is removed. In this way, the number of all read-out circuits which transmit the detection signal output from the first electrodes 31n, can be reduced.

Next, the behavior of the circuit when the radioactive ray comes incident on the radiation detection element 30 will be described with reference to a circuit diagram of FIG. 5. For instance, if the radioactive ray comes incident on the first detection pixel P1 of the radiation detection element 30A, pairs of electrons and holes are generated in this first detection pixel P1, and electric signals (the detection signals) are generated by the bias voltage through transferring the electrons to the first electrode 31n (n=1), and the holes to the second electrode 32m (m=1).

These detection signals are detected by a signal detection block (not shown) through the wiring of No. 1 and the wiring of No. A, respectively connected to corresponding the first electrode 31n (n=1) and the second electrode 32m (m=1).

This signal detection block determines that the radioactive ray came incident on the first detection pixel P1 of the radiation detection element 30A, if the detection signals are simultaneously detected by the wiring of No. 1 and the wiring of No. A.

In this way, the present invention is characterized in that, the radiation detection elements 30 on the support PCB 21 are connected to each other, thus a signal read-out circuit having mutually-perpendicular wiring similar to the conventional DSSD, is formed in a pseudo way, and the incident position of the radioactive ray is identified by the coincidence determination of the detection signals.

With reference to a circuit diagram of FIG. 5, 6 radiation detection elements 30 (m=1 to 6) each of which has 8 detection pixels Pn (n=1 to 8) are used, therefore, the radiation detection module 20 has 48 pixels. Here, the case in which these 48 pixels are read out by 14 read-out circuits, has been explained.

However, the number of the detection pixels Pn is not fixed to such number. Furthermore, as described above, it is the case of (m=n) that the rate of the number of the read-out circuits against the number of the detection pixels Pn becomes least. In addition, in the present embodiment, the detection pixels Pn are arranged in series from 1 to 8 on all of the radiation detection elements 30. However, if each radiation detection element 30 dose not have the duplication of the number from 1 to 8, it is possible to perform the detection. That is to say, the pixels do not have to arrange in series, for example, the pixels can be arranged in series from 1 to 8 on the radiation detection elements 30A, 30C, 30D and 30F, and adversely in series from 8 to 1 on the radiation detection elements 30B and 30E.

In addition, as the present invention is characterized in that a plurality of the radiation detection elements 30 are arranged spindly in one direction in one radiation detection module 20, the consequences of a case when this one radiation detection module 20 goes down can be reduced. That is to say, an absent portion of the image generated when one radiation detection module 20 goes down, can be complemented using the image data of adjacent normal radiation detection modules 20.

In addition, even if the radioactive ray intensely comes incident on a fraction of the radiation detection module 20, as this incident surface of the radioactive ray generally has a certain level of extent, a plurality of the radiation detection modules 20 share the detection of the incident surface of the radioactive ray because of an elongate shape thereof. As a result, the detection signals output from the radiation detection modules 20 are dispersed, a dead time reduces, and a reliability of data increases.

In addition, as signal processing elements such as capacitors and resistances are arranged on the support PCB 21, the high voltage is needed to be applied only to a part of the contact point 22 arranged between the connection section 21 a and the connecting unit 14c. That is to say, the high voltage is needed to be applied only to the high voltage bias wiring 28. As a result, the insulating structure can be simple.

Furthermore, as the density of wiring against the detection pixels Pn can be reduced, the density of the detection pixels Pn can be increased and the image can have a high picture quality.

### EXPLANATIONS OF LETTERS OR NUMERALS

1 semiconductor element

10 radiation image-capturing device

11 image display unit

14 signal detection block

14c connecting unit

15 imaging unit

20 radiation detection module

21 support PCB

21a connection section

22 contact point

23n low voltage bias resistance (signal processing element)

24n low voltage coupling capacitor (signal processing element)

25m high voltage bias resistance (signal processing element)

26m high voltage coupling capacitor (signal processing element)

30, 30A to 30F radiation detection element

31n first electrode

32m second electrode

28 high voltage bias wiring

Pn, P1 to P8 detection pixel (pixel)

1. A radiation detection module comprising:
a radiation detection element including:
a semiconductor element having a plurality of pixels;
a plurality of first electrodes arrayed on a first surface of the semiconductor element;
a second electrode disposed on a second surface of the semiconductor element over the plurality of pixels;
wherein the radiation detection element outputs detection signals through the first electrode and the second electrode when a radioactive ray comes incident on the pixels;
a support PCB being placed in parallel with a direction in which the radioactive ray comes incident, and supporting a plurality of the radiation detection elements arranged perpendicularly to the incident direction, and in a direction in which divided pixels corresponding to the first electrodes of the radiation detection element are arrayed; and
a connection section being detachably connected to an external connecting unit, with bias voltage being applied thereto from the connecting unit, outputting the detection signals to the connecting unit, and mechanically holding the support PCB to the connecting unit;
wherein one of the first electrodes of one of the radiation detection elements is connected to one of the first electrodes of the other radiation detection elements on the support PCB, a position on which the radioactive ray comes incident is identified by simultaneously measuring the detection signals from the first and second electrodes.

2. The radiation detection module according to claim 1, wherein the radiation detection elements are arranged on both sides of the support PCB.

3. The radiation detection module according to claim 1, wherein the radiation detection elements are arranged on one side of the support PCB.

4. The radiation detection module according to claim 1, wherein the support PCB includes a resistance for applying the bias voltage and a capacitor for taking out a signal.

5. The radiation detection module according to claim 1, wherein the radiation detection element includes the semiconductor element having the plurality of pixels.

6. The radiation detection module according to claim 2, wherein the radiation detection element includes the semiconductor element having the plurality of pixels.

7. The radiation detection module according to claim 3, wherein the radiation detection element includes the semiconductor element having the plurality of pixels.

8. The radiation detection module according to claim 4, wherein the radiation detection element includes the semiconductor element having the plurality of pixels.

9. A radiation image-capturing device comprising: the plurality of radiation detection modules according to claim 1 arranged in a plane so that the radioactive ray passing through a collimator comes incident.
